(19) United States
(12) Patent Application Publication
(10) Pub. No.: US 2006/0158554 A1
(43) Pub. Date: Jul. 20, 2006

(54) Method for generating a video pixel clock and apparatus for performing the same

(75) Inventor: Soon-Jae Cho, Suwon-si (KR)

Correspondence Address: F. CHAU & ASSOCIATES, LLC, 130 WOODBURY ROAD, WOODBURY, NY, 11797, US

(73) Assignee: Samsung Electronics Co., LTD, Suwon-si (KR)

(21) Appl. No.: 11/326,536

(22) Filed: Jan. 5, 2006

(30) Foreign Application Priority Data
Jan. 18, 2005 (KR) 2005-4516

(51) Int. Cl. H04N 5/06; H03L 7/00

(52) U.S. Cl. 348/537; 348/521

(57) ABSTRACT

In a method of generating a video pixel clock, a frequency of an output video pixel clock is increased to a first frequency setting when a quantity of data read from a frame buffer storing video data is greater than a reference level. The frequency of the output video pixel clock is decreased to a second frequency setting when the quantity of data read from the frame buffer is less than the reference level. Accordingly, an imbalance between frame rates of input and output image signals may be reduced.

### CROSS-REFERENCE TO RELATED APPLICATION

This application claims priority under 35 USC § 119 to Korean Patent Application No. 2005-4516, filed on Jan. 18, 2005, the contents of which are herein incorporated by reference in their entirety.

### BACKGROUND OF THE INVENTION

1. Field of the Invention

The present invention relates to a display driver, and more particularly to a method for generating a video pixel clock that is used for a display driver and an apparatus for performing the same.

2. Description of the Related Art

Generally, a display driver is used to display images on a display device such as a liquid crystal display (LCD), a plasma display panel (PDP), a cathode ray tube (CRT), a digital lighting processing (DLP) projection system, etc., using an input digital signal or an input analog signal.

Because of the widespread adoption of digital image applications such as digital television, the display driver is required to process image signals in various formats. For example, the display driver may need to process video signals in a National Television System Committee (NTSC) format, an Advanced Television System Committee (ATSC) format, an output format compatible with a digital set-top box, or an output format compatible with a digital versatile disc (DVD).

A video pixel clock is necessary for the display driver to generate a signal corresponding to each pixel of the display device. For example, in a digital lighting processing (DLP) system having 1,280 pixels per horizontal line, the video pixel clock has 1,280 clock periods, which corresponds to each of the 1,280 pixels during a period of a horizontal synchronization signal.

In a typical video application, matching between an input image signal and an output image signal is a concern. In order to process the image signals without accumulating data or generating a loss of data, it is desirable that the output image signal be output in accordance with the frame rate of the input image signal.

When the frame rate of the output image signal is lower than the frame rate of the input image signal, overflow of a frame buffer may occur as the input image signal accumulates. Conversely, when the frame rate of the output image signal is higher than the frame rate of the input image signal, there may not exist an image signal to be output after a predetermined period of time has elapsed.

As the input image signal may be output in various formats having different video pixel clocks, it is difficult to continually generate an output video pixel clock precisely matching an input video pixel clock. To achieve this, a phase-locked loop (PLL) is required to produce a clock output with a precise frequency. However, implementing the phase-locked loop for producing a precise frequency output that matches the input video clock is difficult, and if implemented, the PLL circuit may have an increased complexity, resulting in an increased size. Therefore, manufacturing costs and chip size may be increased.

One approach to overcome the imbalance between the frame rates of the input and output image signals is to repeat or eliminate frames. Namely, when the frame rate of the output image signal is lower than the frame rate of the input image signal, the input image signal is removed for a predetermined time interval. Conversely, when the frame rate of the output image signal is higher than the frame rate of the input image signal, the frame of the input image signal is repeated for a predetermined time interval. Thus, the image signal may not be accumulated when the frame rate of the output image signal is lower than the frame rate of the input image signal and an output image signal may not be exhausted when the frame rate of the output image signal is higher than the frame rate of the input image signal.

However, according to the above conventional technique, frames are merely repeated or eliminated so that the display quality of images may be degraded.

A frame rate conversion scheme may be used to reduce the imbalance between the frame rates of the input and output video pixel clocks while preventing the degradation in the display quality. However, the hardware employed may have increased complexity and access to memory is increased, thereby affecting the bandwidth of a system.

Another approach is to adjust the output video pixel clock by providing a phase difference between an input vertical synchronization signal (VSYNC) and an output VSYNC to a voltage controlled crystal oscillator (VCXO). However, circuitry for calculating the phase differences between the input VSYNC and the output VSYNC is needed, and the use of such circuitry and the voltage controlled crystal oscillator may increase the size of the hardware employed.

Therefore, it is desirable to provide an apparatus and a method for generating a video pixel clock that reduces the imbalance between the frame rate of the input video pixel clock and the frame rate of the output video pixel clock.

### SUMMARY OF THE INVENTION

An exemplary embodiment of the present invention provides a method of generating a video pixel clock in which an imbalance between the frame rates of the input and output image signals are reduced.

Another exemplary embodiment of the present invention provides a method of driving a display device in which an imbalance between the frame rates of the input and output image signals are reduced.

Still another exemplary embodiment of the present invention provides an apparatus for generating a video pixel clock in which an imbalance between the frame rates of the input and output image signals are reduced.

In an exemplary embodiment of the present invention, a method of generating a video pixel clock includes increasing a frequency of an output video pixel clock to a first frequency setting when a quantity of data read from a frame buffer storing video data is greater than a reference level, and decreasing the frequency of the output video pixel clock to a second frequency setting when the quantity of data read from the frame buffer is less than the reference level.

In one aspect, the first frequency setting is higher than a frequency of an input video pixel clock.

In another aspect, the second frequency setting is lower than the frequency of the input video pixel clock.

The method may further include determining the quantity of data read from the frame buffer every time period corresponding to a one-frame period of the input video data.

In one aspect, the determining of the quantity of data is performed using a difference between a read pointer of the frame buffer and a write pointer of the frame buffer.

In another exemplary embodiment of the present invention, a method of driving a display device includes determining a quantity of data read from a frame buffer, wherein the frame buffer stores input video data based on an input video pixel clock, modifying a frequency of an output video pixel clock according to the quantity of data read from the frame buffer, and driving the display device using the output video pixel clock and a video data signal read from the frame buffer according to the output video pixel clock.

In one aspect, the modifying of the frequency of the output video pixel clock includes increasing the frequency of the output video pixel clock when the quantity of data read from the frame buffer is greater than a reference level, and decreasing the frequency of the output video pixel clock when the quantity of data read from the frame buffer is less than the reference level.

In another aspect, the modifying of the frequency of the output video pixel clock includes determining the frequency of the output video pixel clock as a first frequency setting when the quantity of data read from the frame buffer is greater than the reference level, the first frequency setting being higher than a frequency of the input video pixel clock.

In still another aspect, the modifying of the frequency of the output video pixel clock includes determining the frequency of the output video pixel clock as a second frequency setting when the quantity of data read from the frame buffer is less than the reference level, the second frequency setting being lower than the frequency of the input video pixel clock.

In yet another aspect, the determining of the quantity of data is performed using a difference between a read pointer of the frame buffer and a write pointer of the frame buffer.

In still another exemplary embodiment of the present invention, an apparatus for generating a video pixel clock includes a frequency generator configured to generate an output video pixel clock using an input video pixel clock and a frequency adjustment signal, a frame buffer configured to output output video data based on input video data according to the output video pixel clock, wherein the input video data is received on the frame buffer according to the input video pixel clock, and a host controller configured to set a write pointer of the frame buffer according to the input video pixel clock, configured to set a read pointer of the frame buffer according to the output video pixel clock and configured to generate the frequency adjustment signal using the write pointer and the read pointer.

In one aspect, the host controller may check a difference between the write pointer and the read pointer every time period corresponding to a one-frame period of the input video data.

In another aspect, the frequency generator includes a phase-locked loop configured to generate a pre-clock having a first frequency based on the input video pixel clock, and a frequency adjustment unit configured to generate the output video pixel clock having a second frequency lower than the frequency of the pre-clock by removing a predetermined clock pulse of the pre-clock according to the frequency adjustment signal.

### BRIEF DESCRIPTION OF THE DRAWINGS

The present invention will become more apparent to those of ordinary skill in the art by describing, in detail, exemplary embodiments thereof with reference to the attached drawings, wherein like elements are represented by like reference numerals, which are given by way of illustration only and thus do not limit the exemplary embodiments of the present invention.

FIG. 1 is a flowchart illustrating a method of generating a video pixel clock according to an exemplary embodiment of the present invention.

FIG. 2 illustrates a status of a frame buffer according to an exemplary embodiment of the present invention.

FIG. 3 is a graph illustrating a status of a frame buffer according to an exemplary embodiment of the present invention.

FIG. 4 is a timing diagram illustrating an method of modifying a frequency of an output video pixel clock.

FIG. 5 is a flowchart illustrating a method of driving a display device according to an exemplary embodiment of the present invention.

FIG. 6 is a block diagram illustrating an apparatus for generating a video pixel clock according to an exemplary embodiment of the present invention.

FIG. 7 is a block diagram illustrating the frequency generator of FIG. 6.

FIG. 8 is a flowchart illustrating an operation of the host controller of FIG. 6.

### DESCRIPTION OF THE EXEMPLARY EMBODIMENTS

Hereinafter, the present invention will be explained in detail with reference to the accompanying drawings.

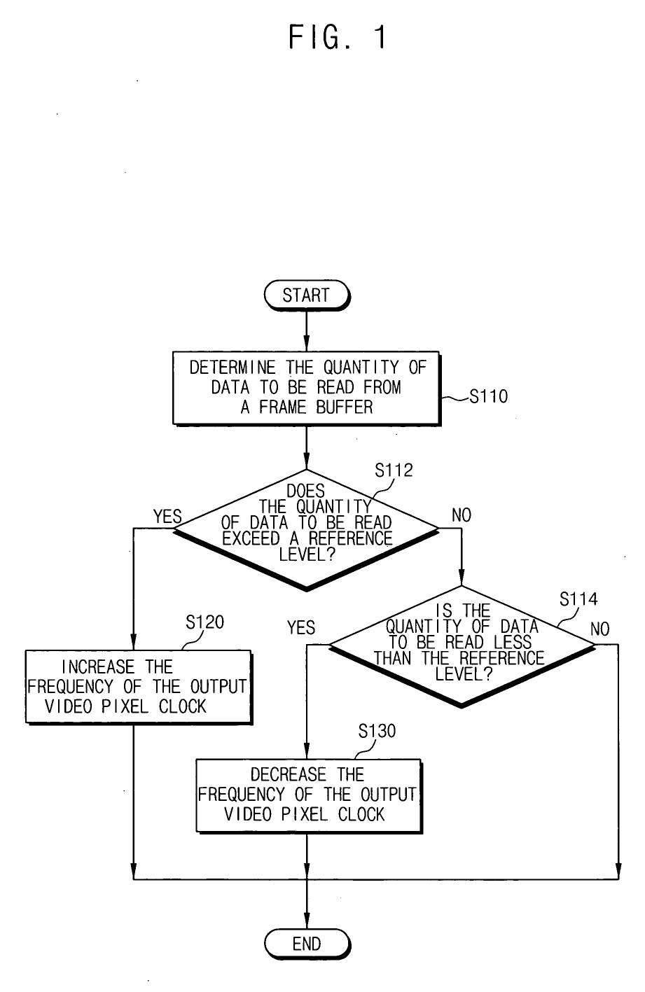

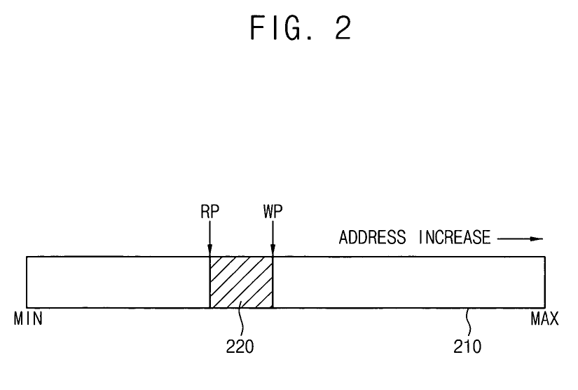

FIG. 1 is a flowchart illustrating a method of generating a video pixel clock according to an exemplary embodiment of the present invention and FIG. 2 illustrates a status of a frame buffer according to an exemplary embodiment of the present invention.

Referring to FIG. 1, the quantity of data to be read from a frame buffer is determined S110. The frame buffer is used to store input video data. For example, the frame buffer may be used to store the video data corresponding to three frames.

The data to be read from the frame buffer is the data that has not been read after the data is written to the frame buffer. The frame buffer may have a read pointer and a write pointer. The write pointer may be increased as the video data is stored in the frame buffer corresponding to the input video pixel clock. The read pointer may be increased as the video data is output from the frame buffer corresponding to the output video pixel clock. In this circumstance, the data to be read from the frame buffer may be obtained by using the difference between the write pointer and the read pointer of the frame buffer.

Referring to FIG. 2, the frame buffer 210 includes the write pointer WP and the read pointer RP. The write pointer WP is used to point to a location where data is written to the frame buffer 210 during a write operation and the read pointer RP is used to point to a location where data is read from the frame buffer 210 during a read operation. For example, the frame buffer 210 may store data corresponding to three frames.

The write pointer WP is increased as the video data is stored in the frame buffer 210 in accordance with the input video pixel clock, and the read pointer RP is increased as the video data is output from the frame buffer 210 in accordance with the output video pixel clock. When the write pointer WP and the read pointer RP increase to reach a maximum value MAX, the write pointer WP and the read pointer RP return to a minimum value MIN as shown in FIG. 2.

A difference 220 between the write pointer WP and the read pointer RP corresponds to the data to be read from the frame buffer 210.

Referring now to FIG. 1, it is determined whether the quantity of data to be read from the frame buffer 210 exceeds a reference level S112. For example, the reference level may be the quantity of data corresponding to one frame of the input video data or output video data. According to an exemplary embodiment of the present invention, it is determined whether the difference 220 between the write pointer WP and the read pointer RP is greater than the data corresponding to one frame. Namely, the data to be read from the frame buffer 210 may be determined as to whether it is greater than the data corresponding to one frame.

When the quantity of data to be read from the frame buffer 210 is greater than the reference level, the frequency of the output video pixel clock is increased S120.

The output video pixel clock may be set to have a first frequency setting higher than the frequency corresponding to the input video pixel clock. The frequency corresponding to the input video pixel clock is the frequency that matches the frame rate of the input video signal to the frame rate of the output video signal. It is preferable that the first frequency setting be produced as close as possible to the frequency corresponding to the input video pixel clock.

When the quantity of data to be read from the frame buffer 210 does not exceed the reference level, then it is determined whether the quantity of data to be read is less than the reference level S114. When the quantity of data to be read is less than the reference level, the frequency of the output video pixel clock is decreased S130. The output video pixel clock may be set to have a second frequency setting lower than the frequency corresponding to the input video pixel clock. It is preferable that the second frequency setting be produced as close as possible to the frequency corresponding to the input video pixel clock.

In one embodiment, the reference level may include more than two reference levels such as an upper reference level and a lower reference level. In this circumstance, the data to be read may be determined as to whether it exceeds the upper reference level or falls below the lower reference level.

It should also be noted that in some alternate implementations, the steps illustrated in FIG. 1 may occur out of the order noted in FIG. 1. Namely, the steps in FIG. 1 may be performed in a reverse order or simultaneously performed.

In addition, the steps in FIG. 1 may be repeated every certain time period. For example, the time period may correspond to a one-frame period of the input video data. For example, suppose that the frequency corresponding to the input video clock is approximately 74.175824 MHz and the frequency that is produced as close as possible to the frequency of approximately 74.175824 MHz may be one of approximately 74.175720 MHz and approximately 74.175935 MHz. For example, the first frequency setting may be approximately 74.175935 MHz and the second frequency setting may be approximately 74.175720 MHz.

According to an exemplary embodiment of the present invention, when the quantity of data to be read from the frame buffer 210 is greater than the reference level, the frequency of the output video pixel clock may be set as the first frequency setting of approximately 74.175935 MHz so that the rate of reading data from the frame buffer 210 is increased to exceed the rate of writing data to the frame buffer 210. When the quantity of data to be read from the frame buffer 210 is less than the reference level, the frequency of the output video pixel clock may be set as the second frequency setting of approximately 74.175720 MHz so that the rate of reading data from the frame buffer 210 falls below the rate of writing data to the frame buffer 210.

[Pseudo Code 1]
if( (WR_PTR - RD_PTR) <= ONE_FRAME)
{
OUT_PIX_FRQ = LOW_SETTING_FRQ;
}
else if( (WR_PTR - RD_PTR) >= ONE_FRAME)
{
OUT_PIX_FRQ = HIGH_SETTING_FRQ;
}

The above example pseudo code 1 may be used to implement the method of generating the video pixel clock according to an exemplary embodiment of the present invention. WR_PTR in the pseudo code 1 may represent the write pointer of the frame buffer 210 and RD_PTR may represent the read pointer RP of the frame buffer 210.

In addition, ONE_FRAME may represent the quantity of data corresponding to one frame and OUT_PIX_FRQ may represent the frequency of the output video pixel clock and HIGH_SETTING_FRQ and LOW_SETTING_FRQ may represent the first and second setting frequencies, respectively.

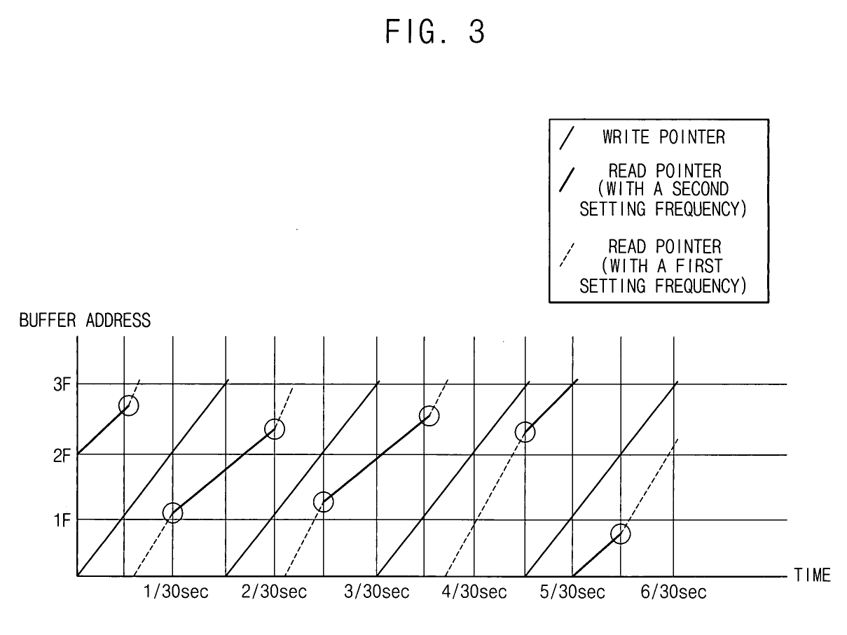

FIG. 3 is a graph illustrating a status of the frame buffer according to an exemplary embodiment of the present invention.

The graph of FIG. 3 shows the status of the frame buffer 210 that is addressed by the write pointer WP and the read pointer RP varying with time.

Referring to FIG. 3, the frame buffer 210 may store data corresponding to a maximum of three frames 3F. When the frame rate is 60 Hz, each frame is stored per every 1/60 second.

Referring to FIG. 3, in a write operation of the frame buffer 210, one frame is written to the frame buffer 210 every 1/60 second. The write pointer WP may increase over time and when the write pointer WP reaches a maximum value 3F, the write pointer WP is initialized to zero. The write pointer WP may be substantially changed linearly with time, and the rate of increment of the write pointer WP may correspond to the frequency of the input video pixel clock.

A read operation of the frame buffer 210 is performed according to the read pointer RP. The read pointer RP may be increased by either a first rate greater than an increase rate of the write pointer WP or a second rate less than an increase rate of the write pointer WP. The rapid first rate of the read pointer RP may correspond to the first frequency setting and the slow second rate of the read pointer RP may correspond to the second frequency setting. Namely, the frequency of the read operation may be switched between the first and second setting frequencies.

The read pointer RP may increase over time and when the read pointer RP reaches a maximum value 3F, the read pointer RP is initialized to zero. The read pointer RP varies in a range substantially the same as the write pointer WP.

For example, the slope of the write pointer WP in FIG. 3 may correspond to a frequency of approximately 74.175824 MHz. Herein, the slope of the read pointer RP may correspond to a frequency of approximately 74.175720 MHz or a frequency of approximately 74.175935 MHz.

The read pointer RP may not be ahead of the write pointer WP because data needs to first be written to the frame buffer 210 before the data is read from the frame buffer 210. The same buffer pointer may not be simultaneously addressed by the write pointer WP and the read pointer RP. Otherwise, a display device may not stably operate. If the read pointer RP advances ahead of the write pointer WP so that the read operation is performed before the data is written to the frame buffer 210, erroneous data may be displayed.

In addition, the write pointer WP may not be ahead of the read pointer RP because data needs to be first read from the frame buffer 210 before new data is written to the frame buffer 210. The same buffer pointer may not be simultaneously addressed by the write pointer WP and the read pointer RP. Otherwise, a display device may not stably operate. If the write pointer WP advances ahead of the read pointer RP to write new data to the frame buffer 210 before the read operation, erroneous data may be displayed.

Referring to FIG. 3, when the gap between the write pointer WP and the read pointer RP is increased to more than a predetermined interval, the rate of increment of the read pointer RP is increased, such that the rate of increment of the read pointer RP corresponds to the first frequency setting. When the gap between the write pointer WP and the read pointer RP is decreased to less than a predetermined interval, the rate of increment of the read pointer RP is decreased, such that the rate of increment of the read pointer RP corresponds to the second frequency setting. Thus, the gap between the write pointer WP and the read pointer RP may maintain a predetermined interval.

Accordingly, when the write pointer WP and the read pointer RP are kept apart from each other by a predetermined interval, the frame rate of the input image signal and the frame rate of the output image signal may be matched to each other. Therefore, it needs not repeat or skip frames due to the imbalance between the frame rates of the input and output image signals.

The difference between the write pointer WP and the read pointer RP of the frame buffer 210 may be checked every time period corresponding to a one-frame period, for example, 1/60 second in the exemplary embodiment of FIG. 3.

Thus, by modifying the frequency of the output video pixel clock between the frequency higher than the frequency of the input video pixel clock (e.g., first frequency setting) and the frequency lower than the frequency of the input video pixel clock (e.g., second frequency setting) according to the status of the frame buffer 210, the imbalance between frame rates of the input and output image signal may be reduced.

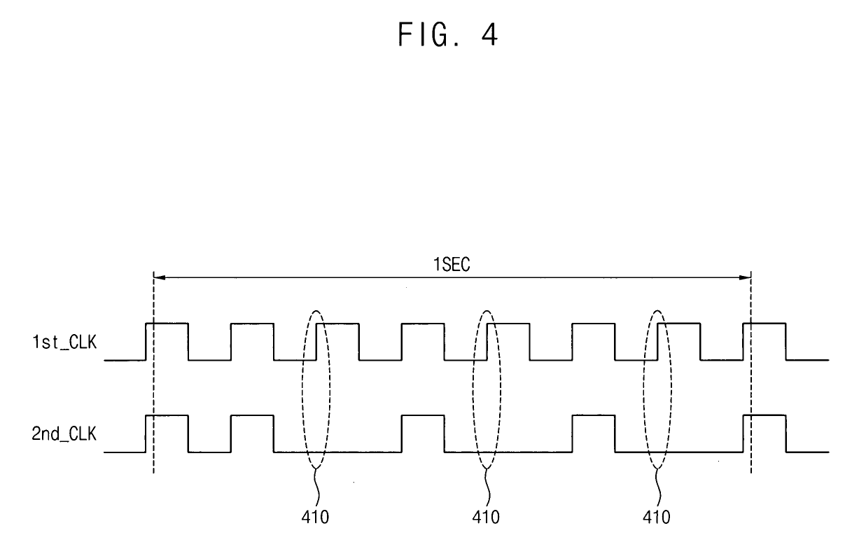

FIG. 4 is a timing diagram illustrating an method of modifying a frequency of the output video pixel clock.

Referring to FIG. 4, pulses of a first clock 1st_CLK are removed by the number of erasures to generate a second clock 2nd_CLK. Namely, based on the number of erasures, three rising transitions 410 of the first clock 1st_CLK are prevented to generate the second clock 2nd_CLK. For example, in FIG. 4, the first clock 1st_CLK has seven rising edges during one second while the second clock 2nd_CLK has four rising edges during the same period of time. The transition of the first clock may be easily prevented by, for example, performing an AND operation of the first clock and logic “0” in a selected clock period.

In FIG. 4, when the clock period is counted based on the rising edge of the clock, the first clock 1st_CLK has a frequency of 7 Hz and the second clock 2nd_CLK has a frequency of 4 Hz. Namely, by removing three clock pulses of the first clock 1st_CLK having a frequency of 7 Hz based on the number of erasures, the second clock 2nd_CLK having a frequency of 4 Hz may be generated.

Using the method of modifying the frequency of the output video pixel clock in FIG. 4, the method of generating the video pixel clock in FIG. 1 may be implemented. For example, the frequency of the clock generated by the phase-locked loop may be set as the first frequency setting and the second frequency setting may be generated by eliminating predetermined pulses of the clock output from the phase-locked loop. Alternatively, for example, predetermined clock pulses of the clock output from the phase-locked loop may be removed by a first number of erasures to generate the first frequency setting and the predetermined clock pulses of the clock output from the phase-locked loop may be removed by a second number of erasures to generate the second frequency setting. Herein, the first number of erasures may be less than the second number of erasures, wherein the first number of erasures and the second number of erasures are integers.

Through various embodiments, the frequency of the output video pixel clock may be set as the first frequency setting or the second frequency setting. For example, the output video pixel clock having a desired frequency (e.g., the first frequency setting or the second frequency setting) may be output by way of modifying parameters applied to the phase-locked loop for generating the frequency of the output video pixel clock.

It should be interpreted that any type of action including modifying the frequency of the output video pixel clock to be lower than the frequency of the input video pixel clock in order to remove the imbalance between the frame rates of the input and output image signals is encompassed within some exemplary embodiments of the present invention.

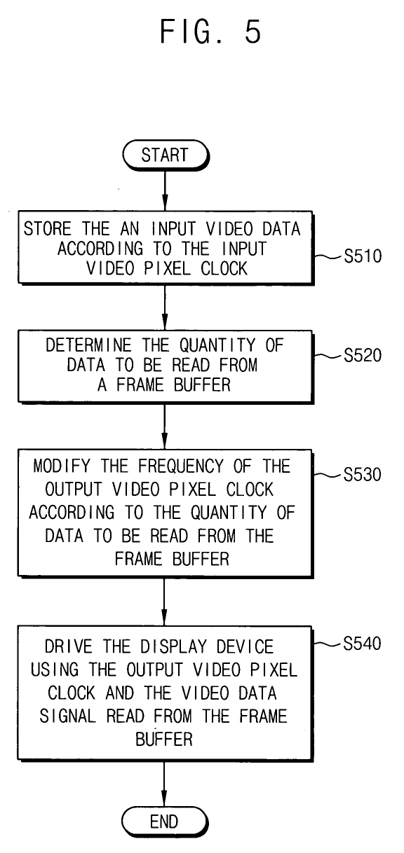

FIG. 5 is a flowchart illustrating a method of driving a display device according to an exemplary embodiment of the present invention.

Referring to FIG. 5, according to an exemplary embodiment of the present invention, the input video data is stored in the frame buffer 210 according to the input video pixel clock S510.

For example, the frame buffer 210 may store the input video data corresponding to three frames.

In addition, the quantity of data to be read from the frame buffer 210 is checked S520.

The data to be read from the frame buffer 210 is the data that has not been read after the data is written to the frame buffer 210.

The frame buffer 210 may have a read pointer RP and a write pointer WP. The write pointer WP may be increased as the video data is stored in the frame buffer 210 corresponding to the input video pixel clock. The read pointer RP may be increased as the video data is output from the frame buffer 210 corresponding to the output video pixel clock. In this circumstance, the data to be read from the frame buffer 210 may be obtained by using a difference between the write pointer WP and the read pointer RP of the frame buffer 210.

The quantity of data to be read from the frame buffer 210 may be checked every certain time period. For example, the time period may correspond to a one-frame period of the input video data.

According to the quantity of data to be read from the frame buffer 210, the frequency of the output video pixel clock is modified S530.

For example, when the quantity of data to be read exceeds a reference level, the frequency of the output video pixel clock may be increased and when the quantity of data to be read is less than the reference level, the frequency of the output video pixel clock may be decreased.

For example, the reference level may be the quantity of the input video data or the output video data corresponding to a one-frame period.

When the quantity of data to be read from the frame buffer 210 is greater than the reference level, the frequency of the output video pixel clock may be set to have the first frequency setting higher than the frequency corresponding to the input video pixel clock. When the quantity of data to be read from the frame buffer 210 is less than the reference level, the frequency of the output video pixel clock may be set to have the second frequency setting lower than the frequency corresponding to the input video pixel clock.

Namely, when the difference between the write pointer WP and the read pointer RP of the frame buffer 210 is greater than the reference level, or quantity of input/output video data corresponding to a one-frame period, the frequency of the output video pixel clock may be set to have the first frequency setting higher than the frequency corresponding to the input video pixel clock. When the difference between the write pointer WP and the read pointer RP of the frame buffer 210 is less than the reference level, the frequency of the output video pixel clock may be set to have the second frequency setting lower than the frequency corresponding to the input video pixel clock.

The output video pixel clock and a video data signal read from the frame buffer 210 according to the output video pixel clock are used to drive a display device S540.

The driving of the display device may include operations that are performed by a typical display driver using the video pixel clock. For example, the display device may be driven by a video graphic processor and an analog display processor to display images on a screen.

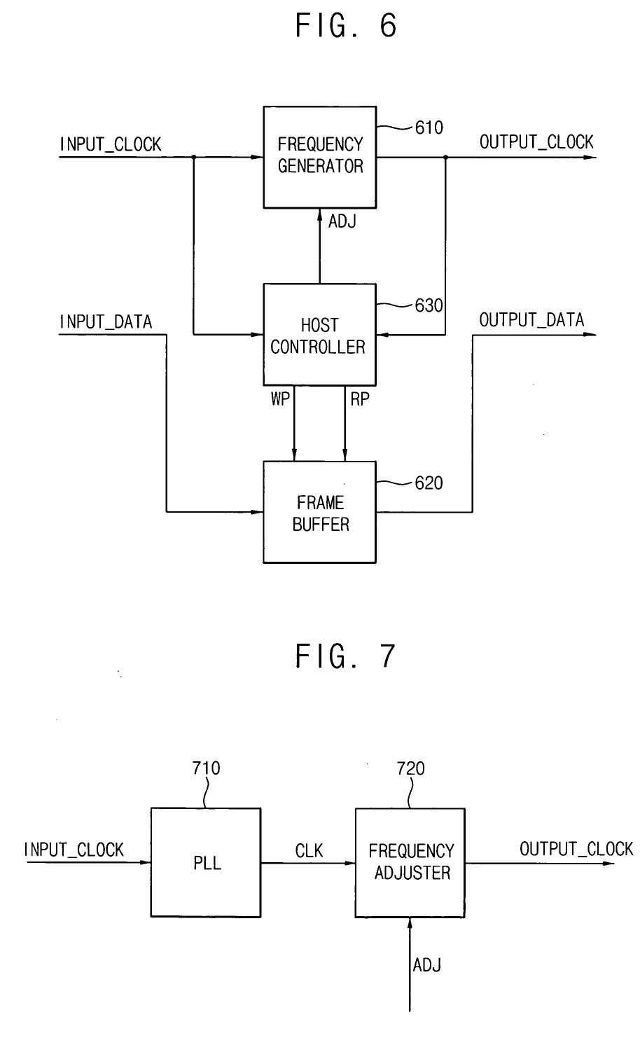

FIG. 6 is a block diagram illustrating an apparatus for generating a video pixel clock according to an exemplary embodiment of the present invention.

Referring to FIG. 6, the apparatus for generating the video pixel clock includes a frequency generator 610, a frame buffer 620 and a host controller 630 according to an exemplary embodiment of the present invention.

The frequency generator 610 generates the output video pixel clock using the input video pixel clock INPUT_CLOCK and a frequency adjustment signal ADJ. The frequency generator 610 may include a phase-locked loop circuit. In this circumstance, the frequency adjustment signal ADJ may include any one of parameters for adjusting an output frequency of the phase-locked loop circuit.

FIG. 7 is a block diagram illustrating the frequency generator of FIG. 6.

Referring to FIG. 7, the frequency generator includes a phase-locked loop 710 and a phase adjustment unit 720.

The phase-locked loop 710 generates a pre-clock CLK based on an input video pixel clock INPUT_CLOCK.

The frequency adjustment unit 720 generates an output video pixel clock OUTPUT_CLOCK having a desired frequency by preventing the transition of the pre-clock CLK based on the frequency adjustment signal ADJ.

The frequency adjustment unit 720 modifies the frequency of the output video pixel clock OUTPUT_CLOCK. In one embodiment, the frequency of the output video pixel clock OUTPUT_CLOCK may be modified by way of the method described with reference to FIG. 4. Namely, the frequency adjustment unit 720 may remove clock pulses of the pre-clock CLK according to the frequency adjustment signal ADJ to generate the output video pixel clock OUTPUT_CLOCK having a frequency lower than the frequency of the pre-clock CLK. For example, the frequency adjustment signal ADJ may include the number of erasures already described in the exemplary embodiment of FIG. 4.

Referring now to FIG. 6, the frame buffer 620 stores input video data INPUT_DATA according to the input video pixel clock INPUT_CLOCK and outputs output video data OUPUT_DATA from the stored date according to the output video pixel clock OUTPUT_CLOCK. For example, the frame buffer 620 may store the video data corresponding to three frames.

The host controller 630 sets the write pointer WP of the frame buffer 620 according to the input video pixel clock INPUT_CLOCK, and sets the read pointer RP of the frame buffer 620 according to the output video pixel clock OUTPUT_CLOCK. Based on the difference between the write pointer WP and the read pointer RP, the frequency adjustment signal ADJ is generated.

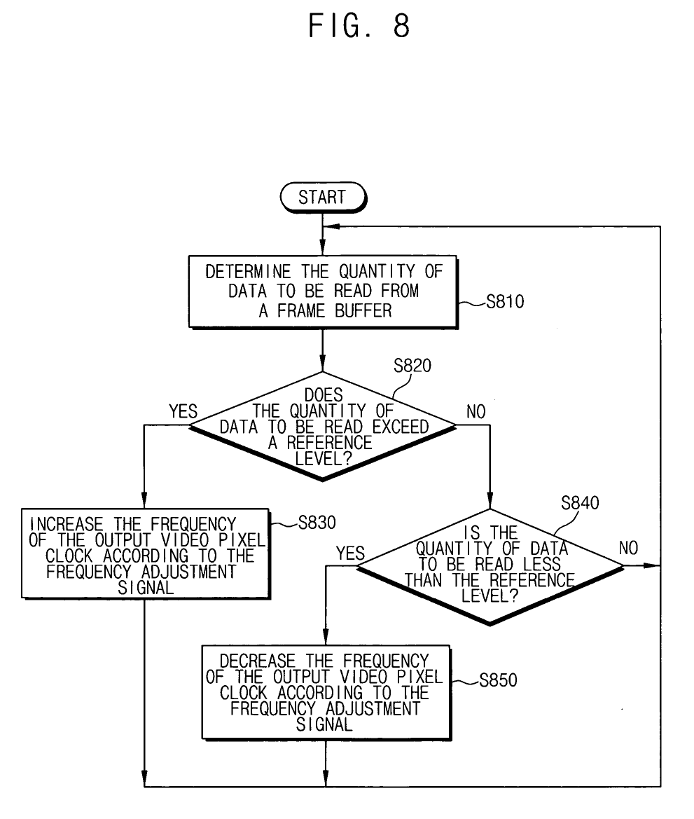

FIG. 8 is a flowchart illustrating an operation of the host controller of FIG. 6.

Referring to FIG. 8, the quantity of data to be read from the frame buffer 620, which stores the input video data, is checked S810.

The data to be read from the frame buffer 620 is the data that has not been read after the data is written to the frame buffer 620.

The frame buffer 620 may have the read pointer RP and the write pointer WP. The write pointer WP may be increased as the video data is stored in the frame buffer 620 corresponding to the input video pixel clock. The read pointer RP may be increased as the video data is output from the frame buffer 620 corresponding to the output video pixel clock. In this circumstance, the data to be read from the frame buffer 620 may be obtained by using a difference between the write pointer WP and the read pointer RP of the frame buffer 620, as already described above.

Whether the quantity of data to be read from the frame buffer 620 exceeds the reference level is determined S820.

The reference level may be the quantity of data that may correspond to one frame of the input video data or the video data that is to be output. Here, the host controller may judge whether or not the difference between the write pointer WP and the read pointer RP of the frame buffer 620 exceeds the quantity of data that correspond to one frame.

When the quantity of data to be read exceeds the reference level, the frequency adjustment signal is generated to increase the frequency of the output video pixel clock S830.

In this circumstance, the frequency adjustment signal may include any one of parameters for adjusting an output frequency of the phase-locked loop. In one embodiment, the frequency adjustment signal may include the number of erasures that is used to prevent the transition of the signal output from the phase-locked loop.

When the quantity of data to be read from the frame buffer 620 does not exceed the reference level, whether the quantity of data to be read is smaller than the reference level is determined S840.

Here, the host controller may judge whether or not the difference between the write pointer WP and the read pointer RP of the frame buffer 620 is less than the quantity of data that correspond to one frame.

When the quantity of data to be read is less than the reference level, the frequency adjustment signal is generated to decrease the frequency of the output video pixel clock S850. The output video pixel clock may be set to have a second frequency setting lower than the frequency corresponding to the input video pixel clock.

In this circumstance, the frequency adjustment signal may include any one of parameters for adjusting an output frequency of the phase-locked loop. In one embodiment, the frequency adjustment signal may include the number of erasures that is used to prevent the transition of the signal output from the phase-locked loop.

In one embodiment, the reference level may include more than two reference levels, such as an upper reference level and a lower reference level. In this circumstance, the data to be read may be determined as to whether it exceeds the upper reference level or falls below the lower reference level.

It should also be noted that in some alternate implementations, the steps illustrated in FIG. 8 may occur out of the order noted in FIG. 8. Namely, the steps in FIG. 8 may be performed in a reverse order or simultaneously performed together.

As described above, by modifying the frequency of the output video pixel clock based on comparison of the quantity of data to be read from the frame buffer 620 and a predetermined reference level, the imbalance between frame rates of the input and output image signal may be reduced.

Although the exemplary embodiments of the present invention discuss modifying the frequency of the output video pixel clock to either the first frequency setting or the second frequency setting, a method of modifying the frequency of the output video pixel clock may vary in different embodiments according to an excess quantity of the data to be read from the reference level.

Having thus described exemplary embodiments of the present invention, it is to be understood that the invention defined by the appended claims is not to be limited by particular details set forth in the above description as many apparent variations thereof are possible without departing from the spirit or scope thereof as hereinafter claimed.

What is claimed is:

1. A method of generating a video pixel clock, comprising:
increasing a frequency of an output video pixel clock to a first frequency setting when a quantity of data read from a frame buffer storing video data is greater than a reference level; and
decreasing the frequency of the output video pixel clock to a second frequency setting when the quantity of data read from the frame buffer is less than the reference level.

2. The method of claim 1, wherein the first frequency setting is higher than a frequency of an input video pixel clock.

3. The method of claim 2, wherein the second frequency setting is lower than the frequency of the input video pixel clock.

4. The method of claim 3, further comprising,
determining the quantity of data read from the frame buffer every time period corresponding to a one-frame period of the input video data.

5. The method of claim 4, wherein the determining of the quantity of data is performed using a difference between a read pointer of the frame buffer and a write pointer of the frame buffer.

6. The method of claim 1, wherein the reference level corresponds to a quantity of data of one frame of an output video data.

7. A method of driving a display device, comprising:
determining a quantity of data to be read from a frame buffer, wherein the frame buffer stores input video data based on an input video pixel clock;
modifying a frequency of an output video pixel clock according to the quantity of data to be read from the frame buffer; and
driving the display device using the output video pixel clock and a video data signal read from the frame buffer according to the output video pixel clock.

8. The method of claim 7, wherein the step of modifying a frequency of an output video pixel clock includes:
increasing the frequency of the output video pixel clock when the quantity of data to be read from the frame buffer is greater than a reference level; and
decreasing the frequency of the output video pixel clock when the quantity of data to be read from the frame buffer is less than the reference level.

9. The method of claim 8, wherein the step of modifying a frequency of an output video pixel clock includes,
changing the frequency of the output video pixel clock to a first frequency setting when the quantity of data to be read from the frame buffer is greater than the reference level, the first frequency setting being higher than a frequency of the input video pixel clock.

10. The method of claim 8, wherein the step of modifying a frequency of an output video pixel clock includes,
changing the frequency of the output video pixel clock to a second frequency setting when the quantity of data to be read from the frame buffer is less than the reference level, the second frequency setting being lower than a frequency of the input video pixel clock.

11. The method of claim 8, wherein the reference level corresponds to a quantity of data of one frame of an output video data.

12. The method of claim 7, wherein the step of determining a quantity of data to be read from a frame buffer is performed every time period corresponding to a one-frame period of the input video data.

13. The method of claim 7, wherein the step of determining a quantity of data to be read from a frame buffer is performed using a difference between a read pointer of the frame buffer and a write pointer of the frame buffer.

14. An apparatus for generating a video pixel clock, comprising:
a frequency generator configured to generate an output video pixel clock using an input video pixel clock and a frequency adjustment signal;
a frame buffer configured to output output video data based on input video data according to the output video pixel clock, wherein the input video data is received on the frame buffer according to the input video pixel clock; and
a host controller configured to set a write pointer of the frame buffer according to the input video pixel clock, configured to set a read pointer of the frame buffer according to the output video pixel clock and configured to generate the frequency adjustment signal using the write pointer and the read pointer.

15. The apparatus of claim 14, wherein a difference between the write pointer and the read pointer is checked by the host controller every time period corresponding to a one-frame period of the input video data.

16. The apparatus of claim 15, wherein a frequency of the output video pixel clock generated by the frequency generator is increased according to the frequency adjustment signal when the difference between the write pointer and the read pointer is greater than a quantity of data of one frame of the output video data.

17. The apparatus of claim 16, wherein the frequency of the output video pixel clock generated by the frequency generator is increased to a first frequency setting according to the frequency adjustment signal when the difference between the write pointer and the read pointer is greater than the quantity of data of one frame of the output video data, the first frequency setting being higher than a frequency of the input video pixel clock.

18. The apparatus of claim 15, wherein a frequency of the output video pixel clock generated by the frequency generator is decreased according to the frequency adjustment signal when the difference between the write pointer and the read pointer is less than a quantity of data of one frame of the output video data.

19. The apparatus of claim 18, wherein the frequency of the output video pixel clock generated by the frequency generator is decreased to a second frequency setting according to the frequency adjustment signal when the difference between the write pointer and the read pointer is less than the quantity of data of one frame of the output video data, the second frequency setting being lower than a frequency of the input video pixel clock.

20. The apparatus of claim 14, wherein the frequency generator includes:
a phase-locked loop configured to generate a pre-clock having a first frequency based on the input video pixel clock; and
a frequency adjustment unit configured to generate the output video pixel clock having a second frequency lower than the frequency of the pre-clock by removing a predetermined clock pulse of the pre-clock according to the frequency adjustment signal.
